(19) United States
(12) Patent Application Publication
(10) Pub. No.: US 2018/0138059 A1
(43) Pub. Date: May 17, 2018

(54) SUBSTRATE LIQUID PROCESSING APPARATUS AND METHOD

(71) Applicant: ZEUS CO., LTD., Osan-si, Gyeonggi-do (KR)

(72) Inventors: Youn Sun CHO, Ansan-si (KR); Han Ok KIM, Seoul (KR)

(73) Assignee: ZEUS CO., LTD., Osan-si, Gyeonggi-do (KR)

(21) Appl. No.: 15/525,339

(22) PCT Filed: May 2, 2016
(86) PCT No.: PCT/KR2016/004615

§ 371 Date: May 9, 2017

(30) Foreign Application Priority Data
Jul. 13, 2015 (KR) 10-2015-0099132

(51) Int. Cl. H01L 21/67; H01L 21/306; H01L 21/02; H01L 21/311; H01L 21/687; H01L 21/3213

(52) U.S. Cl. CPC H01L 21/67051; H01L 21/30604; H01L 21/6708; H01L 21/32134; H01L 21/311; H01L 21/68785; H01L 21/02282

(57) ABSTRACT

The present invention relates to a substrate liquid processing apparatus which etches and cleans a substrate for a semiconductor. The substrate liquid processing apparatus comprises: a substrate supporting unit for supporting a substrate to be spaced apart from an upper portion of a table so that a surface to be processed faces a lower side; a rotational driving unit for driving a rotation axis which rotates the table; and a processing liquid supplying unit for supplying, in a processing space between the table and the substrate, processing liquid that is in a mist state in which a gas is mixed or processing liquid that is in a steam state. According to the substrate liquid processing apparatus, it is possible to uniformize an atmosphere of the processing space between the substrate and the table, and to uniformly spray the processing liquid on the surface to be processed.

### TECHNICAL FIELD

The present invention relates to an apparatus for etching and cleaning a substrate for a semiconductor, and more particularly, to a substrate liquid processing apparatus and method for uniform liquid processing while minimizing usage of a processing liquid supplied to a surface to be processed of a substrate.

### BACKGROUND ART

In order to manufacture semiconductor devices, it is necessary to perform etching and cleaning processes in forming of multilayered thin-films on a substrate.

In general, a wet etching and cleaning apparatus supplies a processing liquid or a cleaning liquid onto a substrate to perform an etching process and a cleaning process while rotating a table, on which a chuck supporting the substrate is installed, and then collects the processing liquid and the cleaning liquid by using a processing liquid collection part having a cup structure around the table.

In the substrate liquid processing apparatus according to the related art, a nozzle is swung along a center of the substrate at an upper side of the substrate, which is supported so that a surface to be processed (hereinafter, referred to as a processed surface) of the substrate faces an upper side, to uniformly supply a processing liquid onto the processed surface. However, when the processing liquid is supplied from the upper side of the substrate, if the liquid processing process is performed at a high temperature, or a chemical liquid having high volatility is used, consumption of the chemical liquid increases due to the evaporation or volatilization of the chemical liquid, and also, fume is generated in the processing chamber.

In another substrate liquid processing apparatus according to the related art, the processing liquid is injected to at least one point from an upper side of the table in the state in which the substrate is supported to that the processed surface of the substrate faces a lower side.

However, it is difficult to uniformly control an atmosphere between the substrate and the table through only the injection of the processing liquid onto the at least one point, and thus, it is difficult to perform the uniform liquid processing on the processed surface.

In order to improve efficiency in removing of the thin film or photoresist deposited on the substrate, the processing liquid having room temperature is supplied to the processed surface, and then, the substrate is heated to perform the liquid processing in a state in which the substrate and the processing liquid are heated at a high temperature of 200° C. to 240° C.

However, when the liquid processing is performed by being heated through a heater in the state in which the processing liquid having room temperature is supplied to the processed surface, defects in shape of a substrate pattern may occur to cause much defects during the liquid processing process for the substrate.

Also, when deionized water having a relatively low temperature is supplied after the liquid processing for the substrate is performed at a high temperature, the chuck may be separated from the substrate by the deformation in shape due to a significant different in temperature between the heated processing liquid and the deionized water, or the processing liquid rapidly decreases in temperature to cause an increase in viscosity of the processing liquid, thereby generating particles.

### DISCLOSURE OF THE INVENTION

### Technical Problem

To solve the problems of the abovementioned background art, an object of the present invention is to provide a substrate liquid processing apparatus that generates a uniform atmosphere between a substrate and a table while minimizing usage of a processing liquid to improve liquid processing efficiency of the substrate.

Also, an object of the present invention is to provide a substrate liquid processing method that prevents defects in shape of a substrate pattern from occurring when liquid processing is performed by being heated through a heater in a state in which a processing liquid is supplied to a processed surface.

Also, an object of the present invention is to provide a substrate liquid processing method in which a substrate decreases in temperature, before a rinse liquid having a relatively much low temperature is supplied after a processing liquid is supplied to the substrate to perform liquid processing on the substrate at a high temperature, to prevent particles from occurring or prevent the substrate from being damaged.

### Technical Solution

To solve the foregoing objects, a substrate liquid processing apparatus for supplying a processing liquid to a surface to be processed of a substrate to perform liquid processing according to the present invention includes: a substrate supporting unit supporting the substrate to be spaced apart from an upper portion of a table so that the surface to be processed faces a lower side; a rotational driving unit driving a rotational shaft that rotates the table; and a processing liquid supplying unit supplying a processing liquid that is in a mist state in which a gas is mixed or a processing liquid that is in a steam state into a processing space between the table and the substrate.

Preferably, the processing liquid supplying unit may inject the processing liquid from the upper portion of the table toward the surface to be processed.

Preferably, the processing liquid supplying unit may mix the processing liquid that is in a liquid state with an inert gas to inject the resultant mixture.

Preferably, the processing liquid may include two kinds or more of chemical liquids, and the processing liquid supplying unit may mix the chemical liquids with the inert gas just before being injected after the chemical liquids are mixed with each other to inject the resultant mixture.

Preferably, the substrate liquid processing apparatus may further include a heating unit heating at least one of the substrate or the processing liquid.

Preferably, the heating unit may include a heater provided above the substrate.

Preferably, the processing liquid supplying unit may include a processing liquid supplying tube receiving the processing liquid from a processing liquid storage part and one or more nozzle parts injecting the processing liquid received from the processing liquid supplying tube.

Preferably, the processing liquid supplying tube may be provided in a hollow part within the rotational shaft.

Preferably, the nozzle parts may be configured so that an injection amount of processing liquid gradually increases in a radius direction of the substrate.

Preferably, each of the nozzle parts may include a body part connected to an upper end of the processing liquid supplying tube and an injection part having one or more injection holes, through which the processing liquid is injected to the surface to be processed, in the body part.

Preferably, at least one of the nozzle parts may be disposed so that a central axis of the body part is out of a rotational axial line of the table.

Preferably, one of the injection holes may be disposed to slantingly inject the processing liquid to a rotational center of the surface to be processed.

Preferably, at least two injection holes of the injection holes may be disposed to inject the processing liquid in directions different from each other with respect to a central axis of the body part.

Preferably, two or more remaining injection holes except for the injection hole through which the processing liquid is injected to the rotational center may be disposed to slantingly inject the processing liquid to the same semicircle of the surface to be processed.

Preferably, at least two injection holes of the injection holes may have sizes different from each other.

Preferably, at least two injection holes of the injection holes may have tilt angles different from each other between a central axis of each of the injection holes and a central axis of the body part.

Preferably, the injection hole having a large tilt angle may have a diameter greater than that of the other injection hole having a small tilt angle.

Preferably, the nozzle parts may be provided in plurality, and the plurality of nozzle parts may have different striking surfaces onto which the processing liquid is injected to the surface to be processed.

Preferably, one of the plurality of nozzle parts may inject the processing liquid to an outer portion of the surface to be processed, and the other one may inject the processing liquid to an inner portion.

Preferably, the substrate liquid processing apparatus may further include a nozzle control unit controlling at least one of a flow rate and a pressure of each of the plurality of nozzle parts.

Preferably, each of the nozzle parts may include a body part connected to an upper end of the processing liquid supplying tube and an injection part having a slit in a radius direction of the substrate in the body part.

Preferably, the body part may extend from the upper portion of the table in the radius direction of the substrate.

Preferably, the body part may have a bent cantilever shape at an upper central portion of the table.

Preferably, the body part may have a fan shape using an upper central portion of the table as a center.

Preferably, the slit may have a gap gradually increasing in the radius direction of the substrate.

Preferably, the body part may include two or more branch tubes that are branched from an upper central portion of the table in the radius direction of the substrate.

Preferably, the body part may include first and second branch tubes that are branched in a diameter direction.

Preferably, the first and second branch tubes may have the same length.

Preferably, the first and second branch tubes may have lengths different from each other.

To solve the foregoing other objects, a substrate liquid processing method for supplying a processing liquid to a surface to be processed of a substrate to perform liquid processing according to the present invention includes: a substrate supporting step of supporting the substrate to be spaced apart from an upper portion of the table so that the surface to be processed faces a lower side; a heating step of heating at least one of the substrate or the processing liquid supplied to the substrate; a liquid processing step of supplying a processing liquid that is in a mist state in which a gas is mixed or a processing liquid that is in a steam state into a processing space between the table and the substrate to perform liquid processing on the surface to be processed.

Preferably, after the substrate supporting step, the substrate liquid processing method may further include: a processing liquid preliminary supplying step of supplying a processing liquid that is in a mist state in which a gas is mixed or a processing liquid that is in a steam state into a processing space between the table and the substrate.

Preferably, in the processing liquid preliminary supplying step, the processing liquid may be supplied for 1 second to 15 seconds.

Preferably, in the processing liquid preliminary supplying step, the processing liquid may be supplied at a temperature of 30° C. to 200° C.

Preferably, the processing liquid may include a sulfuric acid peroxide mixture, and in the processing liquid preliminary supplying step, the processing liquid may be supplied at a high temperature due to reaction heat generated through reaction of sulfuric acid and peroxide.

Preferably, the liquid processing step may be performed at the same time when the substrate rotates or performed after the rotation of the substrate starts.

Preferably, after the liquid processing step, the substrate liquid processing method may further include: a first cleaning step of supplying a rinse liquid having a first temperature to clean the surface to be processed; and a second cleaning step of supplying a rinse liquid having a second temperature less than the first temperature to clean the surface to be processed.

Preferably, after the liquid processing step, the substrate liquid processing method may further include a cleaning step of supplying the rinse liquid to the surface to be processed in a state in which an operation of a heater is finished after the rinse liquid is supplied to the surface to be processed while operating the heater installed above the substrate.

Preferably, the processing liquid may include a chemical liquid that is used in an etching process or a PR strip process for the surface to be processed, and the rinse liquid may include deionized water.

### Advantageous Effects

According to the substrate liquid processing apparatus of the present invention, the processing liquid that is in the mist state in which the gas is mixed or the processing liquid that is in the steam state may be supplied into the space between the table and the substrate to uniformize the atmosphere of the processing space.

Also, according to the present invention, the injection hole having various tilt angles, radius directions, and diameters may be provided to uniformly supply the processing liquid to the processed surface.

Also, according to the present invention, the plurality of nozzle parts may be provided to control the flow rate or pressure of each of the nozzle parts.

Also, according to the present invention, the injection hole having the slit shape may be provided to uniformly inject the processing liquid into the spaced between the substrate and the table.

Also, according to the present invention, the liquid processing may be performed on the substrate by being heated through the heater in the state in which the processing liquid having the high temperature is supplied to the processed surface to prevent the defects in the shape of the substrate pattern from occurring while the liquid processing is performed on the substrate.

Also, according to the present invention, the rinse liquid having the first temperature may be supplied, and then, the rinse liquid having the second temperature less than the first temperature may be supplied to clean the processed surface, thereby suppressing the occurrence of the particles due to the significant temperature difference.

Also, according to the present invention, since the operation of the heater is finished while the rinse liquid is supplied, the supplied rinse liquid may gradually decrease in temperature to suppress the occurrence of the particles due to the significant temperature difference.

### BRIEF DESCRIPTION OF THE DRAWINGS

FIG. 1 is a view illustrating a configuration according to a first embodiment of the present invention.

FIG. 2 is a plan cross-sectional view of a nozzle part according to the first embodiment of the present invention.

FIG. 3 is a plan view of the nozzle part according to the first embodiment of the present invention.

FIG. 4 is a cross-sectional view taken along line A-A of FIG. 3.

FIG. 5 is a cross-sectional view taken along line B-B of FIG. 3.

FIG. 6 is a cross-sectional view taken along line C-C of FIG. 3.

FIG. 7 is a plan view illustrating a striking surface of an injection hole according to the first embodiment of the present invention.

FIG. 8 is a view illustrating a configuration according to a second embodiment of the present invention.

FIG. 9 is a plan view illustrating a striking surface of an injection hole according to the second embodiment of the present invention.

FIG. 10 is a view illustrating a configuration according to a third embodiment of the present invention.

FIG. 11 is a plan cross-sectional view of a nozzle part according to the third embodiment of the present invention.

FIG. 12 is a plan cross-sectional view of a nozzle part according to a fourth embodiment of the present invention.

FIG. 13 is a view illustrating a configuration according to a fifth embodiment of the present invention.

FIG. 14 is a plan cross-sectional view of a nozzle part according to the fifth embodiment of the present invention.

FIG. 15 is a view illustrating a configuration according to a sixth embodiment of the present invention.

FIG. 16 is a plan cross-sectional view of a nozzle part according to the sixth embodiment of the present invention.

FIG. 17 is a flowchart illustrating a substrate liquid processing method according to an embodiment of the present invention.

FIG. 18 is a flowchart illustrating a substrate liquid processing method according to another embodiment of the present invention.

FIG. 19 is a flowchart illustrating a substrate liquid processing method according to further another embodiment of the present invention.

### DESCRIPTION OF MAIN PARTS OF THE DRAWINGS

10: Substrate supporting unit

11: Table

12: Chuck pin

20: Rotational driving axis

21: Rotational shaft

22: Hollow part

30: Processing liquid supplying unit

31: Nozzle part

32: Processing liquid supplying tube

33: Processing liquid storage part

34: Gas storage part

35: Body part

36: Injection part

37: Striking surface

40: Rinse liquid supplying unit

41: Rinse liquid nozzle

42: Rinse liquid supplying tube

43: Rinse liquid storage part

50: Rinse liquid collecting unit

51, 52: Cup

60: Heating unit

### MODE FOR CARRYING OUT THE INVENTION

Hereinafter, embodiments of the present invention will be described with reference to the accompanying drawings. A substrate liquid processing apparatus according to the present invention will be described according to first to sixth embodiments. Here, although components according to the embodiments are basically the same, the components may be partially different from each other. Also, in the several embodiments of the present invention, the components having the same function and effect may be denoted with the same reference symbol.

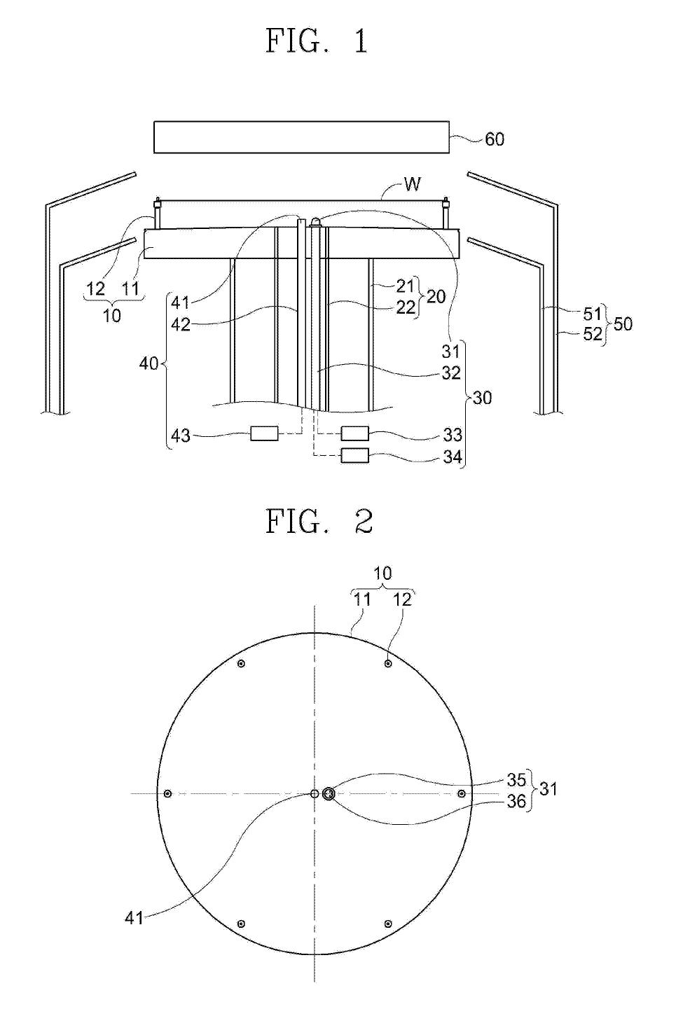

According to a first embodiment of the present invention, as illustrated in FIGS. 1 and 2, a substrate liquid processing apparatus that supplies a processing liquid to a surface to be processed (hereinafter, referred to as a processed surface) to perform liquid processing includes a substrate supporting unit 10, a rotational driving unit 20, a processing liquid supplying unit 30, a rinse liquid supplying unit 40, a processing liquid collecting unit 50, and a heating unit 60.

The substrate supporting unit 10 supports a substrate W so that the substrate W is spaced apart from a table 11. A plurality of chuck pins 12 are installed on an outer upper portion of the table 11 to support the substrate W inward, and the processed surface of the substrate W is supported to face a lower side.

The rotational driving unit 20 drives a rotational shaft 21 disposed on a lower portion of the table 11 to rotate the table 11. Thus, the substrate W supported by the chuck pins 12 may be rotated. A hollow part 22 is formed in the rotational shaft 21. The hollow part 22 serves as a passage through which a processing liquid for liquid-processing the substrate W or an inert gas is supplied.

The processing liquid supplying unit 30 injects the processing solution from the upper side of the table 11 toward the processed surface. Particularly, a processing liquid that is in a mist state in which a gas is mixed or a processing liquid that is a steam state is supplied into a spaced between the table 11 and the substrate W to utilize a two-phase flow nozzle for injecting a mixture in which the processing liquid and the gas are mixed with each other. As described above, since the processing liquid is supplied into the limited processing space, when the liquid processing is performed at a high temperature, or a processing liquid having high volatility is used, the evaporation or the volatilization of the processing liquid may be minimized, and an occurrence of fume may be suppressed.

Here, the term “mist state” means a state in which the processing liquid is mixed with the gas and then injected into the processing space in a droplet state, and the term “steam state” means a state in which the processing liquid is vaporized at a temperature less than a critical temperature.

The rinse liquid supplying unit 40 faces the processed surface and is injected into the processing space between the substrate W and the table 11 to clean the processed surface.

The processing liquid supplied into the processing space between the table 11 and the substrate W may be uniformly supplied into the entire region of the processing spaced by centrifugal force due to the rotation of the substrate W and an exhaust pressure applied to the lower side of the chamber.

Here, when a distance between the table 11 and the substrate W is narrow, since the processing space in which the processing liquid is injected to stay is narrow, an amount of processing liquid to be supplied may be minimized. Particularly, although the processing liquid is supplied at a high temperature or has high volatility, the processing liquid passes the processing space and then is discharged laterally, an amount of processing liquid coming into contact with the processed surface increases to reduce usage of the processing liquid that much.

The processing liquid collecting part 50 includes one or more cups 51 and 52 which are installed around the table 11 so that upper portions of the one or more cups 51 and 52 protrude upward to collect the processing liquid and the rinse liquid, which are discharged from the substrate W.

The heating unit 60 is installed above the substrate W to heat the substrate W, thereby improving liquid processing efficiency of the substrate W. The heating unit 60 may be installed below the substrate W in addition to the upper side of the substrate W or be provided as a heater for directly heating the processing liquid.

Hereinafter, first to fifth embodiments of the present invention will be described in detail according to structures and characteristics of the processing liquid supplying unit and the rinse liquid supplying unit, which constitute the substrate liquid processing apparatus of the present invention.

A substrate liquid processing apparatus according to the first embodiment of the present invention is configured as illustrated in FIGS. 1 to 6.

The processing liquid supplying unit 30 includes a processing liquid storage part 33, a processing liquid supplying tube 32, a nozzle part 31, and a gas storage part 34.

The processing liquid storage part 33 stores a processing liquid for liquid-processing a substrate. Here, the processing liquid may be a chemical liquid that is used in an etching process or a PR strip process for a processed surface.

The processing liquid supplying tube 32 is provided in a hollow part 22 within a rotation shaft 21 to receive the processing liquid from the processing liquid storage part 33.

The nozzle part 31 injects the processing liquid supplied from the processing liquid supplying tube 32 into a processing space between a substrate W and a table 11, thereby uniformly supplying the processing liquid to the processed surface. Here, since the substrate W has an area that gradually increases in a radius direction of the substrate W, it is preferable that an injection amount of processing liquid increases. The nozzle part 31 includes a body part 35 and an injection part 36. Also, one or more nozzle parts 31 may be provided.

The body part 35 is connected to an upper end of the processing liquid supplying tube 32. As illustrated in FIG. 2, the body part 35 is disposed on an upper portion of the table 11, and a central axis A1 of the body part is disposed out of a rotational axial line of the table 11. Thus, an injection angle of the processing liquid that is injected to a center of the processed surface may increase to uniformly supply the processing liquid along the processed surface by centrifugal force of the substrate W without dropping to the table after the processing liquid is injected to the processed surface. Here, a central axis A1 of the body part means a central axial line that is directed in a direction perpendicular to the body part as illustrated in FIGS. 4 to 6.

The processing liquid is mixed with an inert gas to form a mist state or steam state in the body part 35. Since a two-phase flow nozzle structure in which a liquid and a gas are mixed with each other and injected is well known, its detailed description will be omitted.

The injection part 36 is formed on the body part 35 and has one or more injection holes for injecting the processing liquid toward the processed surface.

At least one of the injection hole is disposed to slantingly inject the processing liquid toward the rotational center of the processed surface. Thus, the processing liquid injected to the center of the processed surface is uniformly supplied along the processed surface by the rotation of the substrate W.

At least two injection holes are disposed to inject the processing liquid in directions different from each other with respect to the central axis A1 of the body part. Thus, when compared that the injection holes are disposed in the same direction, the nozzle body part 35 may be reduced in size, and also, a predetermined amount of processing liquid may be supplied over the entire area of the processed surface of the substrate W.

At least two injection holes of the injection holes may have diameter sizes different from each other. Thus, an amount of processing liquid to be injected through each of the injection holes may be adjusted.

At least two injection holes of the injection holes have different tilt angles θ1, θ2, θ3, and θ4 between central axes C1, C2, C3, and C4 and the central axis A1. Thus, the processing liquid may be uniformly supplied to the central portion and an outer portion of the processed surface. Here, each of the central axes C1, C2, C3, and C4 means a line that extends from a center of each of the injection holes.

Here, the injection hole having the large tilt angle may have a diameter greater than that of each of other injection holes. Thus, an injection amount of processing liquid may increase in the radius direction of the processed surface.

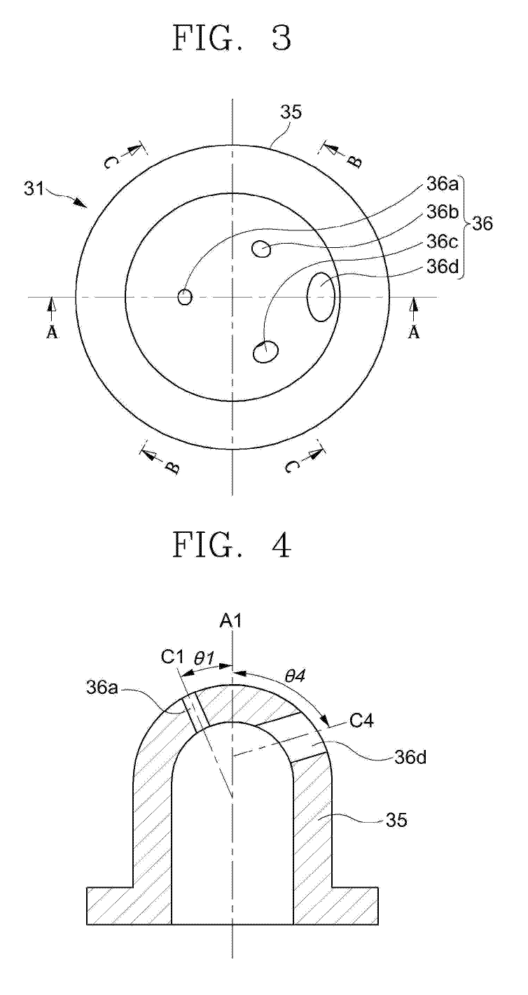

When the nozzle part 31 according to the first embodiment is specifically described with reference to FIGS. 3 to 6, the body part 35 is provided as a nozzle having a cap shape, and the injection part 36 has first to fourth injection holes 36a, 36b, 36c, and 36d.

The central axis C1 of the first injection hole 36a has a first tilt angle θ1 with respect to the central axis A1 of the body part so that the processing liquid is slantingly injected to the rotational center of the processed surface and is disposed toward the rotational center of the processed surface.

The central axis C4 fourth injection hole 36d has a fourth tilt angle θ4 with respect to the central axis A1 of the body part and is disposed to inject the processing liquid in a direction opposite to the first injection hole 36a.

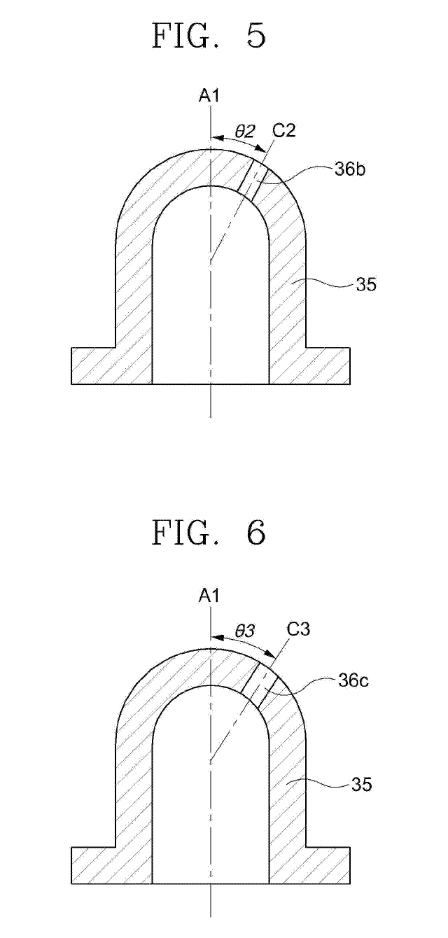

The central axes C2 and C3 of the second and third injection holes 36b and 36c have respectively second and third tilt angles θ2 and θ3 with respect to the central axis A1 of the body part and are respectively disposed adjacent to the fourth injection hole 36d, i.e., on first and second quadrants in FIGS. 5 and 6. The rest injection holes except for the first injection hole through which the processing liquid is injected to the rotational center of the processed surface inject the processing liquid to the same semicircle of the processed surface. Thus, particles generated when the processing liquid is eccentrically injected to the processed surface may be effectively removed.

The processing liquid may be injected through the injection holes in different directions, i.e., slantingly injected at tilt angles different from each other. Thus, the processing liquid may be uniformly supplied to the processed surface by the centrifugal force of the rotating substrate W to perform the uniform liquid processing process.

The first injection hole 36a of the four injection holes is disposed to inject the processing liquid to the rotational center of the processed surface. When comparing the rest injection holes to each other, the tilt angles of the injection holes are largely disposed in order of the fourth, third, and second tilt angles θ4, θ3, and θ2, and the processing liquid is injected adjacent to the edge of the processed surface.

The injection holes have diameters that gradually increase in order of the fourth, third, and second injection holes 36d, 36c, and 36b. Thus, the more the tilt angle increases, the more the diameter increases. That I, since the processed surface has an area to be processed, which gradually increases in the radius direction, it is preferable to the larger the tilt angle, the larger the diameter. However, situationally, although the injection holes have tilt angles different from each other, the injection holes may have the same diameter.

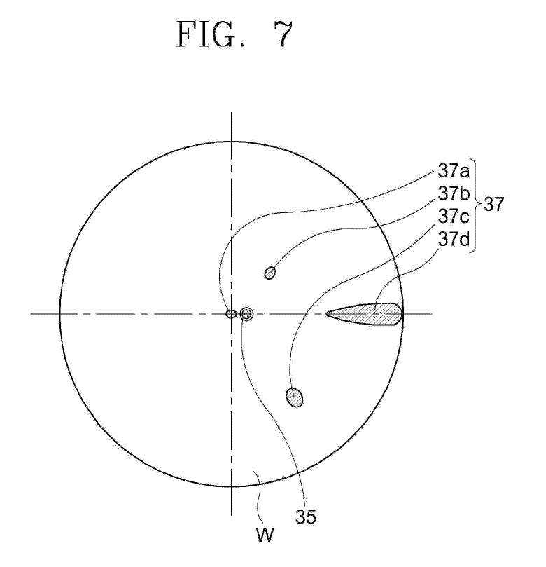

As illustrated in FIG. 7, since striking surfaces 37 of the injection holes have injection angles and diameters, which gradually increase in the radius direction of the processed surface, the striking surfaces have areas that gradually increase in order of the fourth, third, and second injection holes 36d, 36c, and 36b.

The abovementioned first embodiment may be merely an example. The injection holes may be adjusted in number, direction, tilt angle, and diameter as long as the processing liquid is uniformly supplied to the processed surface.

The gas storage part 34 stores a gas to be mixed with the processing liquid so that the processing liquid is injected in the mist state. Here, the gas may be an inert gas such as nitrogen.

The processing liquid supplying unit 30 mixes the processing liquid that is in a liquid state with the inert gas to inject the mixture through the first to fourth injection holes 36a, 36b, 36c, and 36d, thereby uniformly injecting the processing liquid into the processing space between the substrate W and the table 11. Thus, the processing liquid may be uniformly supplied to the rotating processed surface. Here, when the processing liquid includes two kinds or more of chemical liquids, the chemical liquids are mixed with the inert gas in a state in which the chemical liquids are mixed with each other in a separate mixing device, just before being injected, and then, the mixture are injected. For example, when the liquid processing apparatus is a sulfuric acid peroxide mixture (SPM) processing apparatus, sulfuric acid and peroxide are mixed with each other in a separate mixing device, and then, the mixture is mixed with nitrogen just before being injected to inject the mixture in a mist state. Here, the sulfuric acid and the peroxide may be mixed with each other just before being injected to inject the mixture in the mist state at a high temperature due to exothermic reaction.

The rinse liquid supplying unit 40 includes a rinse liquid storage part 43, a rinse liquid supplying tube 42, and a rinse liquid nozzle 41.

The rinse liquid storage part 43 stores a rinse liquid for cleaning the substrate after the liquid processing is performed on the substrate. Here, the rinse liquid may be deionized water. The rinse liquid supplying tube 42 is provided in the hollow part 22 within the rotational shaft 21 to receive the rinse liquid from the rinse liquid storage part 43. The rinse liquid nozzle 41 injects the rinse liquid supplied from the rinse liquid supplying tube 42 into the processing space between the substrate W and the table 11.

The rinse liquid supplying unit 40 is disposed without interrupting a path of the processing liquid supplying unit 30.

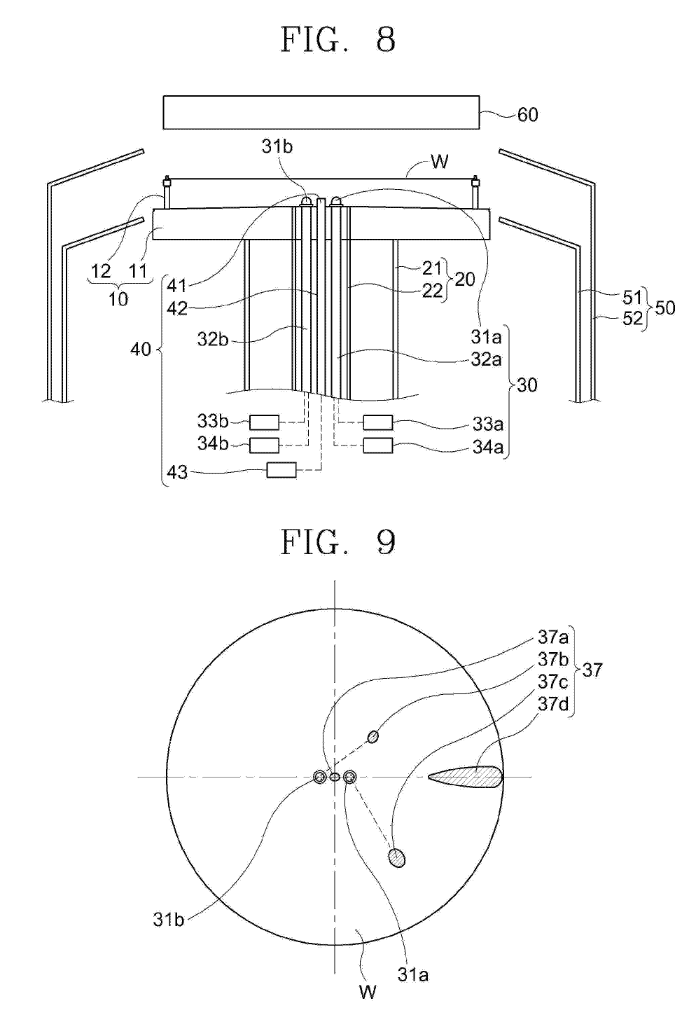

A second embodiment of the present invention is different from the first embodiment in that a plurality of nozzle parts are provided. Hereinafter, components different from those according to the first embodiment will be mainly described with reference to FIGS. 8 and 9.

The nozzle parts 31a and 31b may be provided in plurality. In the second embodiment, two nozzle parts 31a and 31b are provided.

The nozzle parts 31a and 31b inject a processing liquid to a processed surface so that striking surfaces to which the processing liquid is injected are different from each other. Here, one nozzle part 31a may inject the processing liquid to an outer portion of the processed surface, and the other nozzle part 31b may inject the processing liquid to an inner portion of the processed surface.

Particularly, as illustrated in FIG. 9, one nozzle part 31a may have an injection hole for injecting the processing liquid toward striking surfaces 37c and 37d that are disposed on the outer portion of the processed surface, and the other nozzle part 31b may have an injection hole for injecting the processing liquid toward striking surfaces 37a and 37b that are disposed on the inner portion of the processed surface.

Thus, a more amount of processing liquid may be supplied to the outer portion rather than the inner portion of the processed surface.

A nozzle control unit controls at least one of a flow rate and a pressure of each of the above-described nozzle parts 31a and 31b.

Thus, since each of the plurality of nozzle parts 31a and 31b is individually adjusted in flow rate and pressure, the processing liquid may be adjusted in supplying flow rate and pressure for each positions of the striking surfaces 37a, 37b, 37c, and 37d so that the processing liquid is uniformly supplied to the entire surface of the processed surface. If one nozzle part is provided, when the corresponding injection hole is changed in size to change the flow rate and the pressure of the processing liquid supplied to a specific striking surface, the processing liquid injected through the other injection hole is changed in flow rate and pressure of the processing liquid, and thus, it is difficult to individually adjust an injection amount of processing liquid through the injection hole.

The plurality of nozzle parts 31a and 31b are respectively connected to processing liquid supplying tubes 32a and 32b, and the processing liquid supplying tubes 32a and 32b are respectively connected to each of the processing liquid storage parts 33a and 33b and each of the gas storage parts 34a and 34b.

Although not shown, the plurality of nozzle parts may receive the processing liquid and the gas from one processing liquid storage part and one gas storage part.

Two or more nozzle parts may be provided. Although the nozzle parts are disposed on any positions on the table, it is preferable that at least one nozzle part is disposed out of a rotational axial line of the processed surface so that the processing liquid is slantingly injected to a rotational center of the processed surface. Also, the injection hole formed in each of the nozzle parts may be adequately changed in number and disposition as long as the processing liquid is uniformly supplied to the processed surface.

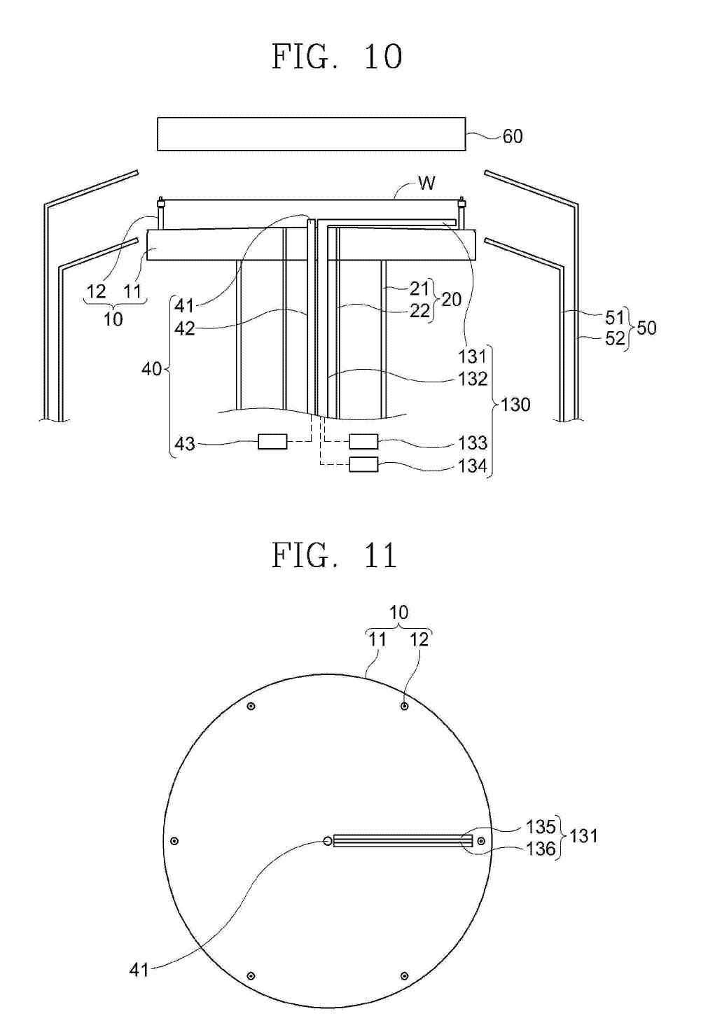

A third embodiment of the present invention is different from the first embodiment in structure of a nozzle part and a rinse liquid nozzle. Hereinafter, components different from those according to the first embodiment will be mainly described with reference to FIGS. 10 and 11.

A body part 135 of the nozzle part 131 is connected to an upper end of a processing liquid supplying tube 132 to extend from an upper portion of a table 11 in a radius direction of a substrate W and has a bent cantilever shape at a central portion on the upper portion of the table 11.

The injection part 136 is formed in the body part 135 in a slit shape in the radius direction of the substrate W to uniformly inject the processing liquid that is in a mist state, in which the processing liquid is mixed with a gas in the body part 135 or the processing liquid that is in a steam state. Here, a two-phase flow nozzle for mixing the processing liquid with the gas may be used. Also, the injection part 136 may be configured so that the slit has a predetermined gap, or an injection amount of processing liquid increases in the radius direction of the substrate W. For example, the gap of the slit may gradually increase in the radius direction to supply a relatively large amount of processing liquid into an outer region that occupies a large volume of a processing space, thereby uniformly supplying the processing liquid to the processed surface of the substrate W.

A processing liquid supplying unit 130 may mix the processing liquid that is in a liquid state with an inert gas to inject the processing liquid that is in a mist state or a steam state through the injection part 136 having the slit shape, thereby uniformly injecting the processing liquid into the processing space between the substrate W and the table 11.

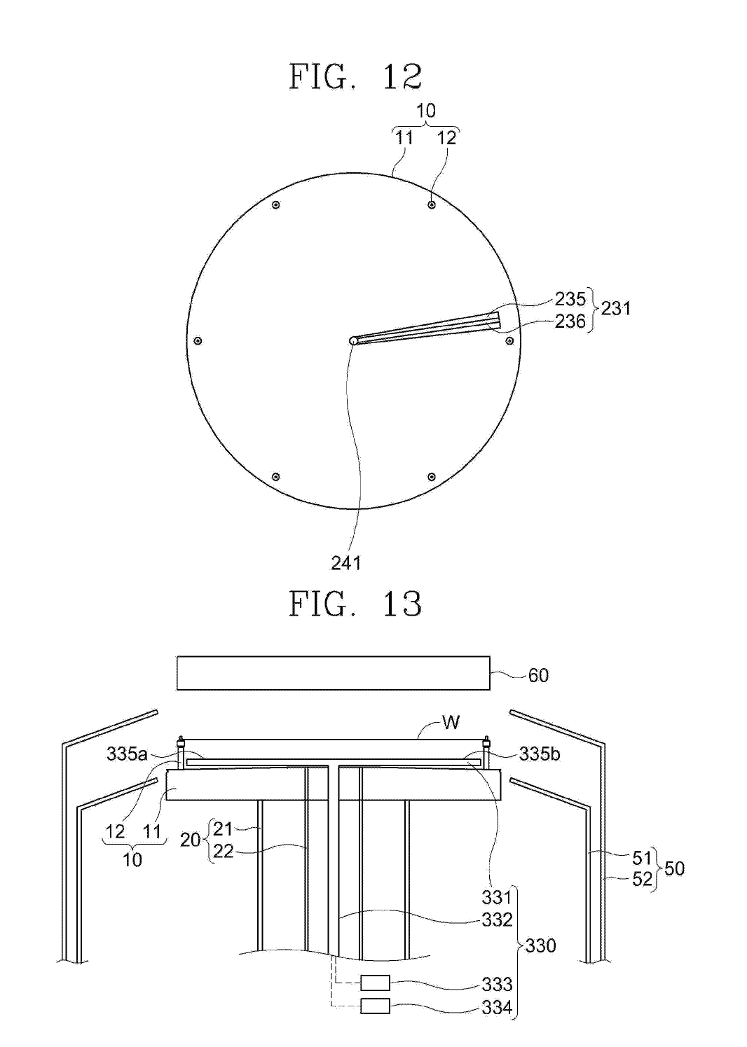

A fourth embodiment of the present invention is different from the third embodiment in structure of a nozzle part and a rinse liquid nozzle. Hereinafter, components different from those according to the third embodiment will be mainly described with reference to FIG. 12.

A body part 235 of the nozzle part 231 has a fan shape using an upper central portion of a table 11 as a center. Since the body part 235 has a relatively large area at an outer portion of the table 11 rather than the central portion of the table 11, a relatively large amount of processing liquid may be supplied to the outer portion rather than the central portion. Thus, the processing liquid that is in a mist state or steam state may be uniformly supplied to a processed surface.

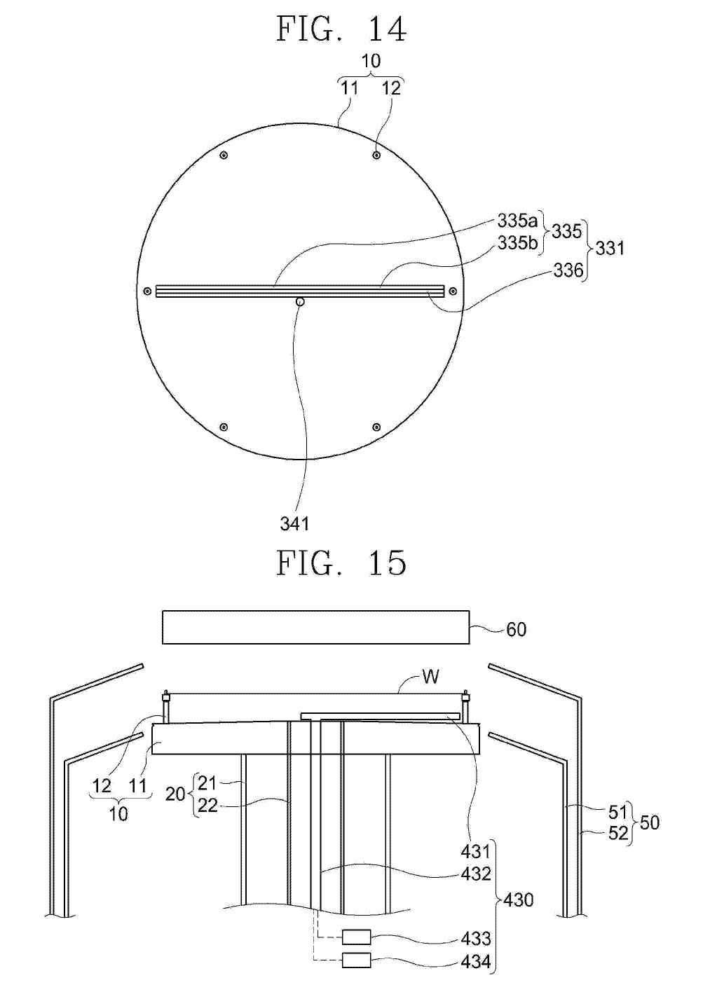

A fifth embodiment of the present invention is different from the third embodiment in structure of a nozzle part and a rinse liquid nozzle. Hereinafter, components different from those according to the third embodiment will be mainly described with reference to FIGS. 13 and 14.

A body part 335 of a nozzle part 331 includes first and second branch tubes 335a and 335b that are branched from a central portion on a table 11.

The first and second branch tubes 335a ad 335b are branched with the same length in a radius direction of the table 11. Thus, the body part 335 has a linear shape from an outer portion of one side of the table 11 to an outer portion of the other side of the table 11 to uniformly supplying a processing liquid into a space between a substrate W and the table 11.

Here, slits formed in the first and second branch tubes 335a and 335b may have the same gap or have gaps that gradually increase in a radius direction like the above-described embodiments.

The body part may have various shapes in addition to the linear shape like the above-described embodiments as long as the body part includes two or more branch tubes that are branched from the central portion on the table in the radius direction. For example, each of the branch tubes may be disposed at a predetermined angle.

A rinse liquid nozzle 341 is disposed on a side surface of a central portion of a nozzle part 331 so that a rinse liquid is injected to a central portion of a processed surface of the substrate without interfering with a path of a processing liquid supplying unit. Although the rinse liquid is injected to the central portion of the processed surface, the rinse liquid may also be supplied to an outer portion of the processed surface by centrifugal force of the substrate W. Thus, the rinse liquid nozzle 341 may be disposed at various positions as long as the rinse liquid is uniformly supplied to the processed surface of the substrate.

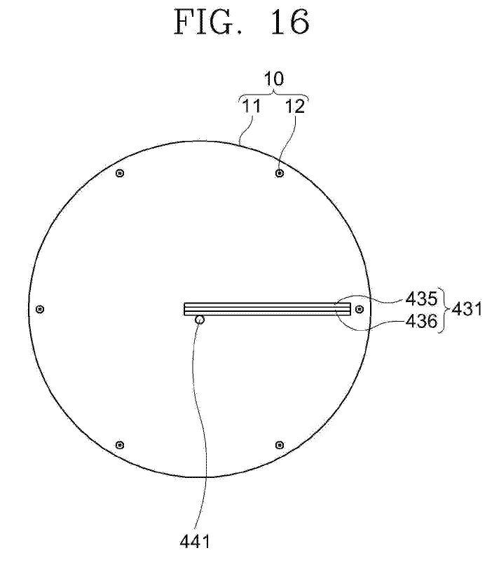

A sixth embodiment of the present invention is different from the fifth embodiment in structure of a nozzle part and a rinse liquid nozzle. Hereinafter, components different from those according to the fifth embodiment will be mainly described with reference to FIGS. 15 and 16.

A body part 435 of a nozzle part 431 includes first and second branch tubes 435a and 435b that are branched from a central portion on a table 11.

The first and second branch tubes 435a and 435b are branched with lengths different from each other in a radius direction of a substrate W. Particularly, the body part 435 has one end that starts from an outer portion of the table 11 and the other end having a linear shape and disposed between the central portion and the outer portion of the table 11 after passing through the central portion of the table 11. Thus, the processing liquid may be supplemented to a central portion of a processed surface of the substrate W to uniformly supply the processing liquid to the entire processed surface.

In a substrate liquid processing method according to another embodiment of the present invention, the above-described substrate liquid processing apparatus may be used by using a method in which a processing liquid is supplied while rotating the substrate to perform liquid processing on a processed surface.

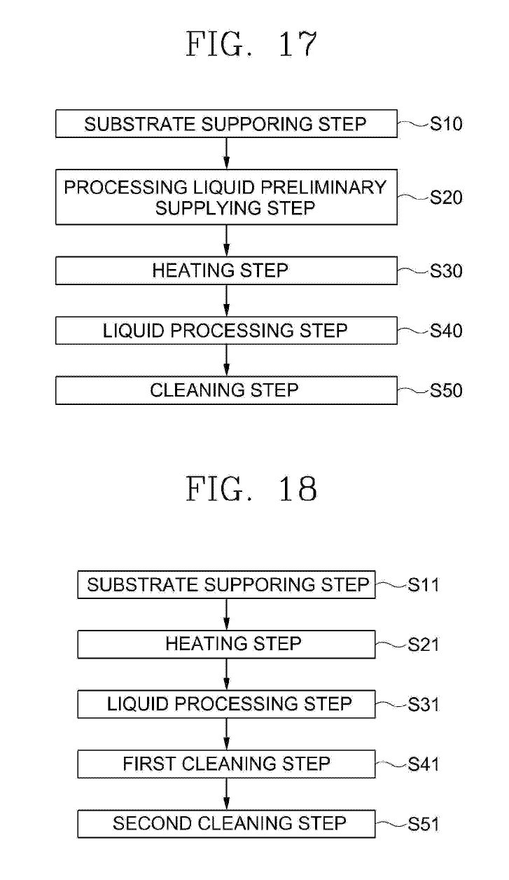

As illustrated in FIG. 17, the substrate liquid processing method according to an embodiment of the present invention includes a substrate supporting step (S10), a processing liquid preliminary supplying step (S20), a heating step (S30), a liquid processing step (S40), and a cleaning step (S50).

In the substrate supporting step (S10), a substrate is supported to be spaced apart upward from a table by a chuck pin so that a processed surface faces a lower side. Since the processed surface faces the lower side, a supply amount of processing liquid may be minimized.

In the processing liquid preliminary supplying step (S20), a processing liquid that is in a mist state in which a gas is mixed or a processing liquid that is in a steam state is supplied into a processing space between the table and the substrate. Here, the processing liquid is uniformly supplied to the processed surface.

In the heating step (S30), at least one of the substrate or the processing liquid supplied to the substrate is heated.

In the liquid processing step (S40), the processing liquid that is in the mist state or the steam state is supplied into the processing space to perform the liquid processing.

In the cleaning step (S50), a rinse liquid is supplied to the processed surface to clean the processed surface.

As described above, in the processing liquid preliminary supplying step (S20) of the substrate liquid processing method, the processing liquid having a high temperature of 30° C. to 200° C., preferably, 60° C. to 150° C. may be supplied. When a sulfuric acid peroxide mixture (SPM) is used as the processing liquid, since pure sulfuric acid has a boiling point of 337° C., and peroxide has a boiling point of 150.2° C., a temperature of the processing liquid to be supplied may be determined according to the present boiling point of the peroxide. However, it is preferable that the processing liquid having the temperature of 30° C. to 200° C. is supplied so that the liquid processing is performed at a higher temperature according to a kind of acid contained in the processing liquid.

When the processing liquid having the high temperature is supplied, an occurrence of defects in shape of a substrate pattern in the heating step (S30) and the liquid processing step (S40) may be prevented to minimize the occurrence of the defects in the liquid processing step (S40).

Also, when the SPM is used as the processing liquid, the processing liquid having a high temperature may be supplied by reaction heat that is generated by reaction between the sulfuric acid and the peroxide may be supplied just before the processing liquid is supplied, as the method for supplying the processing liquid having the high temperature.

As illustrated in FIG. 18, the substrate liquid processing method according to another embodiment of the present invention includes a substrate supporting step (S11), a heating step (S21), a liquid processing step (S31), a first cleaning step (S41), and a second cleaning step (S51).

In the substrate supporting step (S11), a substrate is supported to be spaced apart upward from a table by a chuck pin so that a processed surface faces an upper side.

In the heating step (S21), at least one of the substrate or the processing liquid supplied to the substrate is heated.

In the processing liquid preliminary supplying step (S31), a processing liquid that is in a mist state in which a gas is mixed or a processing liquid that is in a steam state is supplied into a processing space between the table and the substrate to perform liquid processing on a processed surface. The liquid processing step (S31) may be performed at the same time when the substrate rotates or performed after the substrate rotates to uniformly supply the processing liquid to the processed surface.

In the first cleaning step (S41), a rinse liquid having a first temperature is supplied to clean the processed surface.

In the second cleaning step (S51), a rinse liquid having a second temperature less than the first temperature is supplied to clean the processed surface.

As described above, the rinse liquids having the first and second temperatures are successively supplied to perform the cleaning, thereby reducing thermal shock due to a significant temperature difference during the cleaning and suppressing an occurrence of particles.

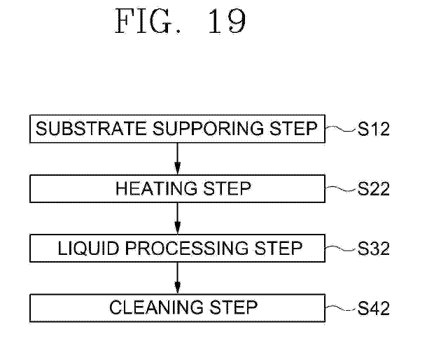

As illustrated in FIG. 19, the substrate liquid processing method according to further another embodiment of the present invention includes a substrate supporting step (S12), a heating step (S22), a liquid processing step (S32), and a cleaning step (S42).

The substrate supporting step (S12), the heating step (S22), and the liquid processing step (S32) are the same as the substrate supporting step (S11), the heating step (S21), and the liquid processing step (S31) according to the above-described embodiment. However, the current embodiment is different from the above-described embodiments in the cleaning step.

In the cleaning step (S42), a rinse liquid is supplied to a processed surface while a heater installed above a substrate operates, and then, the rinse liquid is supplied to the processed surface in a state in which the operation of the heater is finished. Thus, the supplied rinse liquid may gradually decrease in temperature to suppress the occurrence of the particles due to the significant temperature difference.

Although the specific embodiments of the present invention are described with reference to the accompanying drawings, it should be apparent that the scopes of the present invention affect equivalents and modifications within the technical spirit as set forth in the claims.

### INDUSTRIAL APPLICABILITY

The present invention provides a substrate liquid processing apparatus and method for performing uniform liquid processing while minimizing usage of a processing liquid supplied to a processed surface of a substrate.

1. A substrate liquid processing apparatus for supplying a processing liquid to a surface to be processed of a substrate to perform liquid processing, the substrate liquid processing apparatus comprising:
a substrate supporting unit supporting the substrate to be spaced apart from an upper portion of a table so that the surface to be processed faces a lower side;
a rotational driving unit driving a rotational shaft that rotates the table; and
a processing liquid supplying unit supplying a processing liquid that is in a mist state in which a gas is mixed or a processing liquid that is in a steam state into a processing space between the table and the substrate.

2. The substrate liquid processing apparatus of claim 1, wherein the processing liquid supplying unit injects the processing liquid from the upper portion of the table toward the surface to be processed.

3. The substrate liquid processing apparatus of claim 1, wherein the processing liquid supplying unit mixes the processing liquid that is in a liquid state with an inert gas to inject the resultant mixture.

4. The substrate liquid processing apparatus of claim 3, wherein the processing liquid comprises two kinds or more of chemical liquids, and
the processing liquid supplying unit mixes the chemical liquids with the inert gas just before being injected after the chemical liquids are mixed with each other to inject the resultant mixture.

5. The substrate liquid processing apparatus of claim 1, further comprising a heating unit heating at least one of the substrate or the processing liquid.

6. The substrate liquid processing apparatus of claim 5, wherein the heating unit comprises a heater provided above the substrate.

7. The substrate liquid processing apparatus of claim 1, wherein the processing liquid supplying unit comprises a processing liquid supplying tube receiving the processing liquid from a processing liquid storage part and one or more nozzle parts injecting the processing liquid received from the processing liquid supplying tube.

8. The substrate liquid processing apparatus of claim 7, wherein the processing liquid supplying tube is provided in a hollow part within the rotational shaft.

9. The substrate liquid processing apparatus of claim 7, wherein the nozzle parts are configured so that an injection amount of processing liquid gradually increases in a radius direction of the substrate.

10. The substrate liquid processing apparatus of claim 7, wherein each of the nozzle parts comprises a body part connected to an upper end of the processing liquid supplying tube and an injection part having one or more injection holes, through which the processing liquid is injected to the surface to be processed, in the body part.

11. The substrate liquid processing apparatus of claim 10, wherein at least one of the nozzle parts is disposed so that a central axis of the body part is out of a rotational axial line of the table.

12. The substrate liquid processing apparatus of claim 10, wherein one of the injection holes is disposed to slantingly inject the processing liquid to a rotational center of the surface to be processed.

13. The substrate liquid processing apparatus of claim 12, wherein at least two injection holes of the injection holes are disposed to inject the processing liquid in directions different from each other with respect to a central axis of the body part.

14. The substrate liquid processing apparatus of claim 12, wherein two or more remaining injection holes except for the injection hole through which the processing liquid is injected to the rotational center are disposed to slantingly inject the processing liquid to the same semicircle of the surface to be processed.

15. The substrate liquid processing apparatus of claim 12, wherein at least two injection holes of the injection holes have sizes different from each other.

16. The substrate liquid processing apparatus of claim 12, wherein at least two injection holes of the injection holes have tilt angles different from each other between a central axis of each of the injection holes and a central axis of the body part.

17. The substrate liquid processing apparatus of claim 16, wherein the injection hole having a large tilt angle has a diameter greater than that of the other injection hole having a small tilt angle.

18. The substrate liquid processing apparatus of claim 7, wherein the nozzle parts are provided in plurality, and
the plurality of nozzle parts have different striking surfaces onto which the processing liquid is injected to the surface to be processed.

19. The substrate liquid processing apparatus of claim 18, wherein one of the plurality of nozzle parts injects the processing liquid to an outer portion of the surface to be processed, and the other one injects the processing liquid to an inner portion.

20. The substrate liquid processing apparatus of claim 18, further comprising a nozzle control unit controlling at least one of a flow rate and a pressure of each of the plurality of nozzle parts.

21. The substrate liquid processing apparatus of claim 7, wherein each of the nozzle parts comprises a body part connected to an upper end of the processing liquid supplying tube and an injection part having a slit in a radius direction of the substrate in the body part.

22. The substrate liquid processing apparatus of claim 21, wherein the body part extends from the upper portion of the table in the radius direction of the substrate.

23. The substrate liquid processing apparatus of claim 22, wherein the body part has a bent cantilever shape at an upper central portion of the table.

24. The substrate liquid processing apparatus of claim 21, wherein the body part has a fan shape using an upper central portion of the table as a center.

25. The substrate liquid processing apparatus of claim 21, wherein the slit has a gap gradually increasing in the radius direction of the substrate.

26. The substrate liquid processing apparatus of claim 21, wherein the body part comprises two or more branch tubes that are branched from an upper central portion of the table in the radius direction of the substrate.

27. The substrate liquid processing apparatus of claim 26, wherein the body part comprises first and second branch tubes that are branched in a diameter direction.

28. The substrate liquid processing apparatus of claim 27, wherein the first and second branch tubes have the same length.

29. The substrate liquid processing apparatus of claim 27, wherein the first and second branch tubes have lengths different from each other.

30. A substrate liquid processing method for supplying a processing liquid to a surface to be processed of a substrate while rotating the substrate to perform liquid processing, the substrate liquid processing method comprising:
a substrate supporting step of supporting the substrate to be spaced apart from an upper portion of the table so that the surface to be processed faces a lower side;
a heating step of heating at least one of the substrate or the processing liquid supplied to the substrate;
a liquid processing step of supplying a processing liquid that is in a mist state in which a gas is mixed or a processing liquid that is in a steam state into a processing space between the table and the substrate to perform liquid processing on the surface to be processed.

31. The substrate liquid processing method of claim 30, after the substrate supporting step, further comprising: a processing liquid preliminary supplying step of supplying a processing liquid that is in a mist state in which a gas is mixed or a processing liquid that is in a steam state into a processing space between the table and the substrate.

32. The substrate liquid processing method of claim 31, wherein, in the processing liquid preliminary supplying step, the processing liquid is supplied for 1 second to 15 seconds.

33. The substrate liquid processing method of claim 31, wherein, in the processing liquid preliminary supplying step, the processing liquid is supplied at a temperature of 30° C. to 200° C.

34. The substrate liquid processing method of claim 31, wherein the processing liquid comprises a sulfuric acid peroxide mixture, and
in the processing liquid preliminary supplying step, the processing liquid is supplied at a high temperature due to reaction heat generated through reaction of sulfuric acid and peroxide.

35. The substrate liquid processing method of claim 30, wherein the liquid processing step is performed at the same time when the substrate rotates or performed after the rotation of the substrate starts.

36. The substrate liquid processing method of claim 30, after the liquid processing step, further comprising:
a first cleaning step of supplying a rinse liquid having a first temperature to clean the surface to be processed; and
a second cleaning step of supplying a rinse liquid having a second temperature less than the first temperature to clean the surface to be processed.

37. The substrate liquid processing method of claim 30, after the liquid processing step, further comprising a cleaning step of supplying the rinse liquid to the surface to be processed in a state in which an operation of a heater is finished after the rinse liquid is supplied to the surface to be processed while operating the heater installed above the substrate.

38. The substrate liquid processing method of claim 36, wherein the processing liquid comprises a chemical liquid that is used in an etching process or a PR strip process for the surface to be processed, and the rinse liquid comprises deionized water.

39. The substrate liquid processing method of claim 37, wherein the processing liquid comprises a chemical liquid that is used in an etching process or a PR strip process for the surface to be processed, and the rinse liquid comprises deionized water.
